(19) United States
(12) Patent Application Publication
(10) Pub. No.: US 2026/0079513 A1
(43) Pub. Date: Mar. 19, 2026

(54) VOLTAGE REGULATOR

(71) Applicant: Taiwan Semiconductor Manufacturing Company, Ltd., Hsinchu (TW)

(72) Inventor: Perng-Fei YUH, Hsinchu (TW)

(21) Appl. No.: 18/885,082

(22) Filed: Sep. 13, 2024

(51) Int. Cl. G05F 1/575; G11C 5/14; H03F 3/26

(52) U.S. Cl. CPC G05F 1/575; G11C 5/147; H03F 3/265

(57) ABSTRACT

A voltage regular system includes a global voltage generator circuit having a reference input terminal configured to receive a reference voltage and an output terminal configured to output a gate signal that replicates the reference voltage. A plurality of driver circuits each have an input terminal connected to the output terminal of the global generator circuit. An output terminal of each of the driver circuits is connected to a corresponding one or more of a plurality of memory macros. The driver circuits are each configured to output a control signal that replicates the reference voltage to its corresponding memory macro(s).

### BACKGROUND

Reference voltage generators, such as low-dropout (LDO) regulators, often are used in semiconductor devices. For instance, an LDO regulator is typically used to provide a well-specified and stable direct-current (DC) voltage. Generally, a LDO regulator is characterized by its low dropout voltage, which refers to a small difference between respective input voltage and output voltage. An example application for an LDO regulator is a semiconductor memory device, where an LDO regulator may be used to provide a bit line or word line voltage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a block diagram generally illustrating an example of a memory system in accordance with some disclosed embodiments.

FIG. 2 is a schematic diagram illustrating an example of a voltage regulator circuit in accordance with some disclosed embodiments.

FIG. 3 is a schematic diagram illustrating another example of a voltage regulator circuit in accordance with some disclosed embodiments.

FIG. 4 is a schematic diagram illustrating an example of a local driver circuit in accordance with some disclosed embodiments.

FIG. 5 is a schematic diagram illustrating another example of a local driver circuit in accordance with some disclosed embodiments.

FIG. 6 is a schematic diagram illustrating a further example of a voltage regulator circuit in accordance with some disclosed embodiments.

FIG. 7 is a schematic diagram illustrating a further example of a local driver circuit in accordance with some disclosed embodiments.

FIG. 8 is a flow diagram illustrating an example of a voltage regulator method in accordance with some disclosed embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A low-dropout (LDO) voltage regulator provides a specified and stable direct-current (DC) output voltage (e.g., a regulated output voltage) based on an input voltage (e.g., an unregulated input voltage) with a low dropout voltage. The “dropout voltage” used herein refers to a minimum voltage across the (LDO) voltage regulator to maintain the output voltage being regulated. Even though the input voltage, provided by a power source, falls to a level very near that of the output voltage and is unregulated, the LDO voltage regulator can still produce the output voltage that is regulated and stable. Such a stable characteristic enables the LDO voltage regulator to be used in a variety of integrated circuit (IC) applications. Foir instance, on-chip LDO voltage regulators are used to provide regulated voltages to bit-lines and/or word-lines in large-scale memory arrays, such as DRAM, MRAM, RRAM, and the like.

In order to save area, a shared and centralized LDO is sometimes adopted for multiple memory macros or portions of a memory array. However, wire resistance of a connector increases with an increase in the number of connected macros, and voltage drop becomes worse with such an increased number of macros. Because of such IR drops, strong power-meshes are used to distribute the LDO output voltages to all memory arrays, which uses additional metal tracks and increases process costs. Moreover, large dynamic load currents and macro capacitive loads can make LDO design difficult, since a large compensation capacitor is used to make the LDO stable, which in turn reduces speed of the LDO. Some attempted solutions may use several local LDO regulators to drive respective macros or memory partition, but this can increase area and power overhead, and increase cost.

Aspects of the present disclosure relate to a voltage regular system that includes a global voltage generator connected to each of a plurality of distributed, local driver circuits. Each of the local driver circuits, for example, outputs voltage signals to a respective memory macro of a memory system, where the output signal output by the local drive circuits replicates a reference voltage received by the global voltage generator.

In various disclosed examples, a feedback loop is provided only at the global voltage generator circuit. The local drivers have no feedback loop nor compensation capacitor, thus improving area and power efficiency. The disclosed arrangements further provide a smaller IR drop when outputting the voltage signals to the memory macros because the local drivers are situated close to memory macros or partitions.

Since the feedback is provided at the global voltage generator and not at the local drivers, accurate voltage outputs can be output by the global voltage regulators since lower speed, larger size feedback circuits can be employed. Size of the distributed local driver circuits is reduced, using local power supplies, fast push-pull circuits, and no feedback loop.

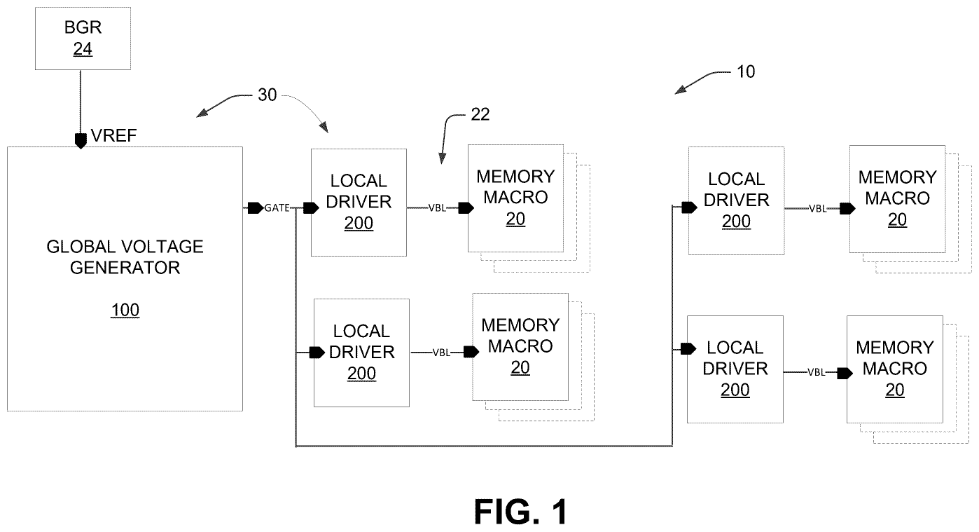

FIG. 1 illustrates an example memory system 10 in accordance with disclosed embodiments. The illustrated system 10 includes a plurality of memory macros 20, each of which include a plurality of memory cells. In various examples the memory device 10 is a large scale memory, for instance, greater than a gigabit or several megabit array. The memory cells of the memory macros 20 may be DRAM, SRAM, MRAM, RRAM, OTP, and the like, though the disclosure is not limited to a particular memory type.

The memory system 10 further includes a voltage regulator system 30 that is configured to output a voltage signal to the memory macros 20. In the illustrated example, the voltage regulator system 30 is configured to output a memory control signal, such as a bit line signal VBL to the memory macros 20, though in various configurations the voltage regulator system 30 may output other memory control signals to the memory macros 20, such as word line signals, source line signals, enable signals, etc.

The voltage regular system 30 is separated into multiple parts, including a global voltage generator circuit 100 and a plurality of distributed local driver circuits 200, each of which is connected to one or more memory macros 20 by conductive lines 22. In some embodiments, the global voltage generator circuit 100 is an LDO circuit that receives a voltage reference signal VREF. The VREF signal is provided by a bandgap regulator circuit 24 in some implementations. Since the local driver circuits 200 are located closer to the memory macros 20, the conductive lines 22 can be shorter, reducing resistance of the lines 22. In some examples, the global voltage generator 100 provides a gate bias signal GATE that replicates the reference voltage VREF received at its input, which is used to drive various portions of the memory macros 20. The distributed local drivers 200 receive the gate bias voltage output the global voltage generator 100, and output the desired output voltage to the memory macros 20.

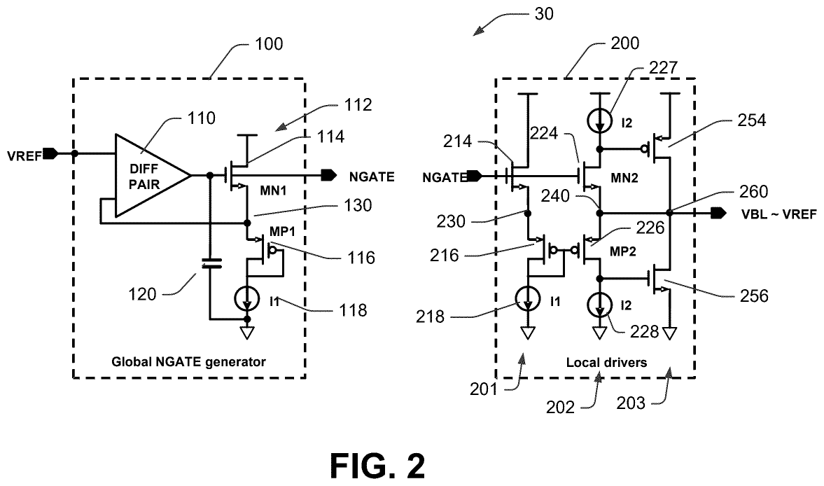

FIG. 2 illustrates further aspects of an example of the voltage regulator system 30. The example of FIG. 2 shows examples of the global voltage generator circuit 100 and one of the distributed local driver circuits 200. The global voltage generator circuit 100 is configured to output a bias voltage signal to control one or more transistors of the distributed local driver circuits 200, which output a bit line voltage signal VBL that replicates the reference voltage VREF input to the global voltage generator circuit 100.

In illustrated examples, the global voltage generator circuit 100 and the distributed local driver circuits 200 employ p-type and n-type metal-oxide-semiconductor field-effect transistors (MOSFETs), referred to herein as PMOS and NMOS transistors, respectively. Other transistor technologies are within the scope of the disclosure. The example of FIG. 2 is configured to output an NGATE signal to bias NMOS transistors of the distributed local driver circuit 200 to in turn provide the bit line voltage signal VBL that replicates the reference voltage VREF. However, the disclosure is not limited to outputting an NGATE bias signal by the global voltage generator circuit 100 or outputting a VBL signal by the distributed local driver circuit 200.

The global voltage generator circuit 100 includes a differential amplifier 110 that has a first input terminal, a second input terminal and an output terminal. The first input terminal is connected to a reference voltage signal VREF, which is received from a band gap circuit, for example. In some implementations, the reference voltage VREF is a voltage level (e.g. 1 volt) appropriate for biasing components of the distributed local driver circuit 200 to output voltage signals to memory macros 20 to operate the memory arrays as desired. Thus, the global voltage generator circuit 100 is configured to output a bias signal NGATE that replicates (i.e. is close to) the VREF signal to bias component(s) of the distributed local driver circuit 200 as desired to drive the memory arrays of the memory macros 20.

A feedback loop 112 is connected between the output terminal of the differential amplifier 110 and the second input terminal of the differential amplifier 110, such that the differential amplifier 110 can compare the output signal NGATE to the reference signal VREF. The feedback loop 112 includes an amplifier circuit such as a source follower amplifier, which includes an MN1 NMOS transistor 114 having a first source/drain (S/D) terminal connected to a first voltage rail, and a second S/D terminal connected to a node 130 that is connected to the second input terminal of the differential amplifier 110. In various examples disclosed herein, the first voltage rail is a Vdd voltage rail, though the disclosure is not so limited. As used herein, source/drain (S/D) terminal(s) may refer to a source or a drain, individually or collectively dependent upon the context. The gate terminal of the MN1 transistor 114 is connected to the output of the differential amplifier 110.

An MP1 PMOS transistor 116 has one S/D terminal connected to the node 130 and its other S/D terminal connected to an I1 current source 118. The MP1 transistor 116 is diode connected in a common source configuration. The I1 current source 118 is connected to a second voltage rail, and a compensation capacitor 120 is connected between the output terminal of the differential amplifier 110 and the second voltage rail. In various examples disclosed herein, the second voltage rail is a ground or Vss voltage rail, though the disclosure is not so limited. The global voltage generator circuit 100 is thus configured to establish a voltage level at the node 130 that replicates or is very close to the reference voltage VREF.

The output terminal of the global voltage generator circuit 100 is connected to input terminals of each of the distributed local driver circuits 200. In the example of FIG. 2, each of the distributed local driver circuits 200 has a first driver stage 201. The first driver stage 201 is a source follower stage that includes an input transistor. In FIG. 2, the input transistor is an NMOS transistor 214 with a first S/D terminal connected to the first voltage rail and a second S/D terminal connected to a node 230. The gate terminal of the NMOS transistor 214 is connected to the input terminal of the distributed local driver circuit 200. In other words, the gate of the input NMOS transistor 214 receives the NGATE signal output by the global voltage generator circuit 100. A PMOS transistor 216 has one S/D terminal connected to the node 230 and its other S/D terminal connected to a current source 218. As with the MP1 transistor 116, the PMOS transistor 218 is diode connected. The current source 218 is connected to the second voltage rail.

The distributed local driver circuit 200 further includes a second driver state, which is a second source follower stage 202 in the illustrated example. The second source follower stage 202 includes an MN2 NMOS transistor 224 has its gate terminal connected to the input terminal of the distributed local driver circuit 200. In other words, the gate of the MN2 transistor 224 receives the NGATE signal output by the global voltage generator circuit 100. One S/D terminal of the MN2 transistor 224 is connected to an I2 current source 227, while the other S/D terminal of the MN2 transistor 224 is connected to a node 240. The I2 current source 227 is further connected to the first voltage rail. The node 240 is connected to a first S/D terminal of an MP2 PMOS transistor 226, which has its second S/D terminal connected to an I2 current source 228. The current source 228 is further connected to the second or ground voltage rail. The gate of the MP2 transistor 226 is connected to the gate terminal of the PMOS transistor 216. Unless otherwise noted, in the examples discussed herein the I1 current is the same as the I2 current, or I1=I2.

The distributed local driver circuit 200 also includes a third stage 203, which is a buffer stage including a push-pull arrangement. The push-pull amplifier stage 203 includes a PMOS transistor 252 connected between the first voltage rail and an output node 260. An NMOS transistor 254 is connected between the output node 260 and the second voltage rail. The NMOS transistor 254 has its gate connected to the junction of the current source 227 and the MN2 transistor 224, and the PMOS transistor 256 has its gate connected to the junction of the current source 228 and the MP2 transistor 226.

As noted above, the feedback loop 112 of the global voltage generator circuit 100 is situated on the source side of the source follower configuration. Thus, the voltage at the node 130 is about the reference voltage VREF plus the gate-to-source voltage (VGS) of the MN1 transistor 114 (VREF+VGS of MN1). The first amplifier stage 201 of the distributed local driver circuit 200 is a source follower stage in the illustrated example. The gate of the NMOS transistor 214 receives the NGATE signal from the global voltage generator circuit 100, which is the same or very close to the reference voltage VREF. The source follower configuration of the first amplifier stage 201 is also connected to the I1 current source 218. If the NMOS transistor 214 and the PMOS transistor 216 are manufactured similarly to the MN1 transistor 114 and the PMOS transistor 216, and the current is the same through these transistors, the VGS of the NMOS transistor 214 replicates (i.e. is the same or very close to) the VGS of the MN1 transistor 114 of the global voltage generator circuit 100. Accordingly, the voltage at the node 230 will be the same or close to the voltage at the node 130. Moreover, if the I2 current level is the same as the I1 current level, the VGS of the MN2 transistor 224 will replicate be the same or close to the VGS of the NMOS transistor 214 and the MN1 transistor 114. As such, the voltage at the node 240 will replicate the voltage levels at nodes 130 and 230.

The third amplifier stage 203 is a buffer stage for outputting the VBL signal. For example, if the VBL output voltage at the node 260 (and at the node 240) drops, the VGS level of the MN2 transistor 224 increases. This results in an increase in the current of the transistor 227, reducing the bias voltage at the gate of the NMOS transistor 254 and increasing current to the NMOS transistor 254.

Thus, rather than output the VBL signal directly from the global voltage generator circuit 100 to the memory macros 20, the local 100 includes the feedback loop 112 to facilitate outputting a bias signal NGATE to the distributed local driver circuit 200 that replicates the input signal VREF. The bias signal NGATE is used by the distributed local driver circuit 200 to generate the VBL output signal that replicates the reference voltage VREF, without the need for a large feedback loop at the distributed local driver circuit 200.

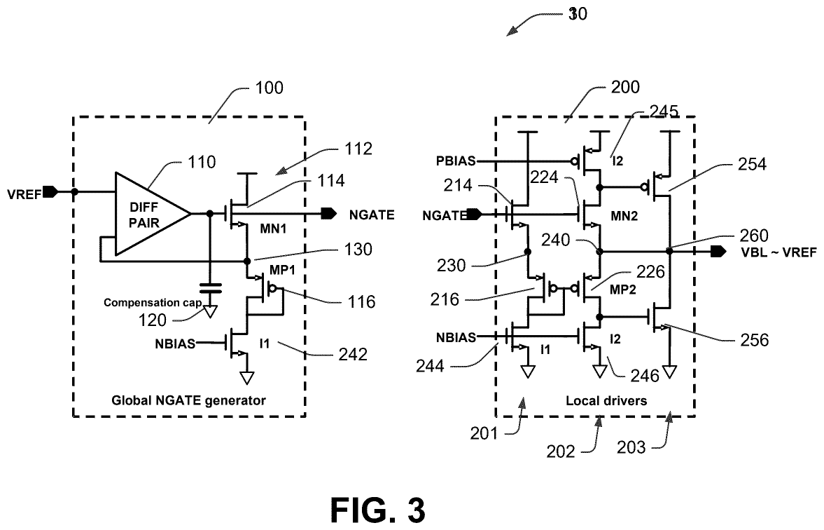

FIG. 3 illustrates an example implementation of the global voltage generator circuit 100 and distributed local driver circuit 200 shown in FIG. 2. In FIG. 3, the I1 and I2 current sources 118, 218, 227 and 228 are replaced with specific components to achieve the desired current levels. More specifically, an NMOS transistor 242 is connected between the ground voltage rail and the MP1 transistor 116. The gate of the NMOS transistor 242 is connected to an NBIAS signal that is configured to bias the NMOS transistor 242 to achieve the I1 current level. Similarly, an NMOS transistor 244 is connected in the first stage 201 between the ground voltage rail and the PMOS transistor 216, with its gate connected to the NBIAS signal to bias the NMOS transistor 244 the same or similar as the NMOS transistor 242 to achieve the I1 current level. A PMOS transistor 245 and an NMOS transistor 246 are included in the second stage 202. The PMOS transistor 245 is connected between the Vdd voltage rail and the MN2 transistor 224 with its gate connected to a PBIAS signal, and the NMOS transistor 246 is connected between the ground rail and the MP2 transistor 226 with its gate connected to the NBIAS signal. The PMOS transistor 245 and the NMOS transistor 246 are thus biased to provide the desired I2 current, which is the same or close to the I1 current.

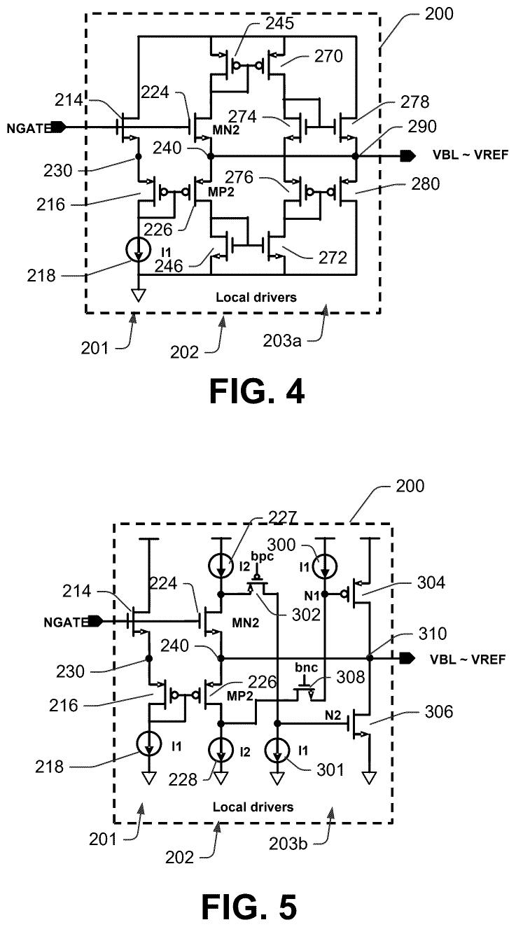

FIG. 4 illustrates an example of an alternative distributed local driver circuit 200 that includes a current mirror push-pull stage. In the example of FIG. 4, the distributed local driver circuit 200 includes essentially the same first two stages 201 and 202 of the example shown in FIGS. 2 and 3. More specifically, the distributed local driver circuit 200 of FIG. 4 has the first source follower stage 201 with the NMOS transistor 214 having its first S/D terminal connected to the first voltage rail and its second S/D terminal connected to the node 230. The gate terminal of the NMOS transistor 214 is connected to the input terminal of the distributed local driver circuit 200 to receive the NGATE signal output by the global voltage generator circuit 100. The PMOS PMOS transistor 216 has one S/D terminal connected to the node 230 and its other S/D terminal connected to the I1 current source 218. The I1 current source 218 is connected to the second (ground) voltage rail.

The second source follower stage 202 includes the MN2 NMOS transistor 224 with its gate terminal connected to the input terminal of the distributed local driver circuit 200 to receive the NGATE signal output by the global voltage generator circuit 100. One S/D terminal of the MN2 transistor 224 is connected to the I2 current source 227, while the other S/D terminal of the MN2 transistor 224 is connected to the node 240. The I2 current source 227 is further connected to the first voltage rail. The node 240 is connected to the first S/D terminal of the MP2 PMOS transistor 226, which has its second S/D terminal connected to the I2 current source 228. The current source 228 is further connected to the second or ground voltage rail. The gate of the MP2 transistor 226 is connected to the gate terminal of the PMOS transistor 216.

The third stage 203a of the distributed local driver circuit 200 is a current mirror push-pull stage that includes a PMOS transistor 270 and an NMOS transistor 272 respectively connected to the PMOS transistor 245 and NMOS transistor 246 as current mirrors. Further, NMOS transistors 274 and 278, and PMOS transistors 276 and 280 are connected to form current mirrors in a push-pull configuration. The current mirror stage 203a has an output node 290 at a junction of the NMOS transistor 278 and the PMOS transistor 280, where the VBL output voltage is provided to the memory macros 20.

FIG. 5 illustrates a further embodiment of the distributed local driver circuit 200, which uses a transconductance amplifier arrangement that allows a lager gate voltage swing. As with the previous examples of the local driver circuits, the distributed local driver circuit 200 includes the stages 201 and 202 arranged similarly to the examples shown in FIGS. 2-4. The first source follower stage 201 includes the NMOS transistor 214 having its first S/D terminal connected to the first voltage rail (e.g. Vdd) and its second S/D terminal connected to the node 230. The gate terminal of the NMOS transistor 214 is connected to the input terminal of the distributed local driver circuit 200 to receive the NGATE signal output by the global voltage generator circuit 100. The PMOS PMOS transistor 216 has one S/D terminal connected to the node 230 and its other S/D terminal connected to the I1 current source 218. The I1 current source 218 is connected to the second (ground) voltage rail.

The second source follower stage 202 includes the MN2 NMOS transistor 224 with its gate terminal connected to the input terminal of the distributed local driver circuit 200 to receive the NGATE signal output by the global voltage generator circuit 100. One S/D terminal of the MN2 transistor 224 is connected to the I2 current source 227, while the other S/D terminal of the MN2 transistor 224 is connected to the node 240. The I2 current source 227 is further connected to the first voltage rail. The node 240 is connected to the first S/D terminal of the MP2 PMOS transistor 226, which has its second S/D terminal connected to the I2 current source 228. The current source 228 is further connected to the second or ground voltage rail. The gate of the MP2 transistor 226 is connected to the gate terminal of the PMOS transistor 216.

The third stage 203b of the distributed local driver circuit 200 includes a PMOS transistor 302 connected between the second S/D terminal of the MN2 transistor 224 and an I1 current source 301. The PMOS transistor 302 is further connected to the gate of an NMOS transistor 306 in a common gate cascode configuration. The gate of the PMOS transistor 302 receives a bias voltage bpc. An NMOS transistor 308 is connected between the second S/D terminal of the MP2 transistor 226 and another I1 current source 300. The NMOS transistor 308 is further connected to the gate of a PMOS transistor 304 in a common gate cascode configuration. The gate of the NMOS transistor 308 receives a bias voltage bnc. An output node 310 is situated at the junction of the PMOS transistor 304 and the NMOS transistor 306.

For instance, if there is strong current loading at the output node 310 (e.g. from the connected memory macros 20), the voltage level at the output node 310 will drop. The VBL output voltage will thus be lower than the steady-state output value, and the voltage at the node 240 will also drop. The current through the MN2 transistor 224 will accordingly increase from that of its quiescent state, and current through the cascode PMOS transistor 302 will decrease (i.e. I2-MN2 current). The I1 current is now stronger or higher than the current through the transistor 302, causing the N2 bias voltage level to decrease and reduce the bias voltage at the gate of the NMOS transistor 306.

Further, when the voltage at the node 240 is reduced, less current flows through the MP2 transistor 226 (gate bias voltage of the MP2 transistor 226 set by the first stage 201 remains constant), resulting in more current draining through the cascode NMOS transistor 308, which reduces the N1 bias voltage. The reduced N1 bias voltage cases more current to flow through the PMOS transistor 304 to the output node 310, restoring the VBL output voltage to the VREF level. If the output voltage at the node 310 increases, the distributed local driver circuit 200 will operate in the opposite manner, increasing the N2 bias voltage to turn on the NMOS transistor 306 to drain current from the output node 310, and decreasing the N1 bias voltage to turn off the PMOS transistor 304 to reduce current flowing to the output node 310, reducing the voltage at the node 310 to the desired VBL level (i.e. VREF). The common gate cascode configuration provides for rail-to-rail voltage swings for the bias voltages N1 and N2, allowing a larger gate swing for the transistors 304 and 306.

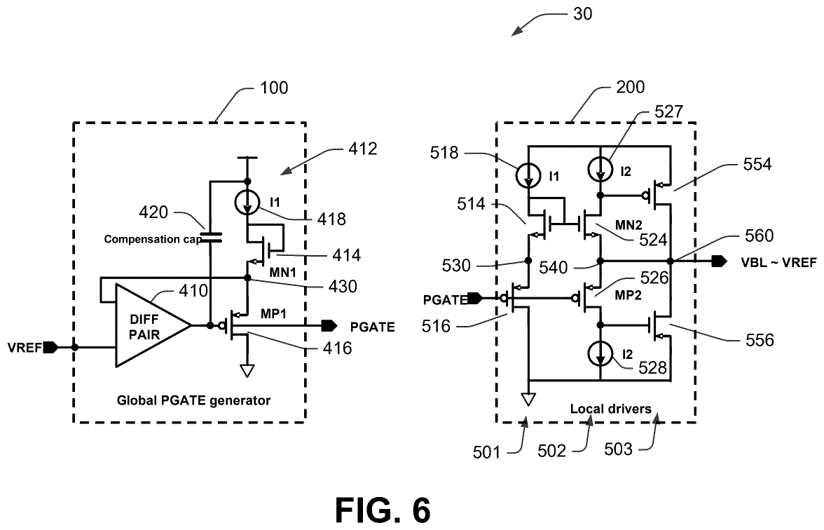

The examples discussed above are configured to output an NGATE signal to bias NMOS transistors of the various local driver circuits. However, the disclosure is not limited to outputting an NGATE bias signal for controlling NMOS devices. FIG. 6 illustrates an example voltage regulator system 30a in which the global voltage generator circuit 100 is configured to output a PGATE bias signal for biasing PMOS transistors of a distributed local driver circuit 200. The PGATE bias signal, and thus the VBL output signal, replicate the VREF signal received by the global voltage generator circuit 100. It is noted that the disclosure is not limited to outputting a bit line signal VBL.

The global voltage generator circuit 100 shown in the example of FIG. 6 includes a differential amplifier 410 that has a first input terminal, a second input terminal and an output terminal. The first input terminal is connected to the reference voltage signal VREF. As with earlier embodiments, the VREF signal may be received from a bandgap reference circuit, for example. A feedback loop 412 is connected between the output terminal of the differential amplifier 410 and the second input terminal of the differential amplifier 410, such that the differential amplifier 410 can compare the output signal PGATE to the reference signal VREF. An MN1 NMOS transistor 414 has one S/D terminal connected to an I1 current source 418 and its other S/D terminal connected to a node 430. The transistor 418 is diode connected in a common source configuration. The current source 418 is connected to the first voltage rail (Vdd), and a compensation capacitor 420 is connected between the output terminal of the differential amplifier 410 and the first voltage rail. The global voltage generator circuit 100 is thus configured to establish a voltage level at the node 430 that replicates or is very close to the reference voltage VREF.

An MP1 PMOS transistor 416 has a first S/D terminal connected to the node 430 and a second S/D terminal connected to the second voltage rail. The gate terminal of the transistor 416 is connected to the output of the differential amplifier 110.

The output terminal of the global voltage generator circuit 100 is connected to input terminals of each distributed local driver circuit 200. The distributed local driver circuit 200 of FIG. 6 has a first source follower stage 501 that includes an NMOS transistor 514 that has one S/D terminal connected to an I1 current source 518 and its other S/D terminal connected to a node 530. The PMOS transistor 518 is diode connected. The I1 current source 518 is connected to the first voltage rail. A PMOS transistor 516 has a first S/D terminal connected to the node 530 and a second S/D terminal connected to the second voltage rail. The gate terminal of the PMOS transistor 516 receives the PGATE signal output by the global voltage generator circuit 100. As with the NMOS-based distributed local driver circuit 200 discussed above, the node 530 is configured to replicate the voltage at the node 430 (i.e. VREF) of the global voltage generator circuit 100.

The distributed local driver circuit 200 further includes a second source follower stage 502, in which an MP2 PMOS transistor 526 has its gate terminal connected to the gate of the PMOS transistor 516 and as such, also receives the PGATE signal output by the global voltage generator circuit 100. One S/D terminal of the MP2 PMOS transistor 526 is connected to an I2 current source 528, while the other S/D terminal of the MP2 transistor 526 is connected to a node 540. The I2 current source 528 is further connected to the second voltage rail. An I2 current source 527 is connected to a first S/D terminal of an MN2 NMOS transistor 524, which has its second S/D terminal connected to the node 540. The current source 527 is further connected to the first voltage rail. The gate of the MN2 transistor 524 is connected to the gate terminal of the transistor 514.

The distributed local driver circuit 200 includes a push-pull amplifier stage 503 that includes a PMOS transistor 554 connected between the first voltage rail and an output node 560. An NMOS transistor 556 is connected between the output node 560 and the second voltage rail. The PMOS transistor 554 has its gate connected to the junction of the current source 527 and the MN2 transistor 524, and the NMOS transistor 556 has its gate connected to the junction of the current source 528 and the MP2 transistor 526.

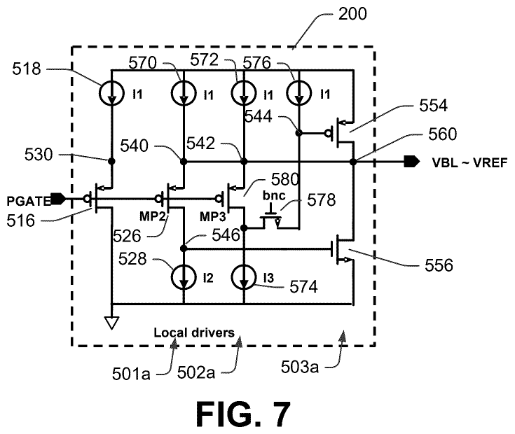

FIG. 7 illustrates an alternative embodiment of the PMOS-based local driver circuit 200. The distributed local driver circuit 200 also receives the PGATE bias signal from the global voltage generator circuit 100 and is configured to output the VBL output signal that replicates the VREF signal. The first driver stage 501a includes the I1 current source 518, which is connected to the PMOS transistor 516 at the node 530. The PMOS transistor 516 is connected between the node 530 and the second voltage rail, with its gate terminal connected to receive the PGATE signal output by the global voltage generator circuit 100.

The second driver stage 502a includes an I1 current source 570, which is connected to the MP2 PMOS transistor 526 at a node 540. The MP2 PMOS transistor 526 is connected between the node 540 and the I2 current source 528, which is connected to the second voltage rail. The gate terminal of the MP2 PMOS transistor 526 is connected to receive the PGATE signal output by the global voltage generator circuit 100.

A third driver stage 504 includes an I1 current source 572, which is connected to a PMOS transistor 580 at a node 542. The PMOS transistor 580 is connected between the node 542 and an I3 current source 574, which is connected to the second voltage rail. In the example of FIG. 7, I1=I2=I3. The gate terminal of the PMOS transistor 580 is also connected to receive the PGATE signal output by the global voltage generator circuit 100.

The distributed local driver circuit 200 of FIG. 7 further includes a push-pull amplifier stage 503a that includes the PMOS transistor 554 connected between the first voltage rail and the output node 560. The output node 560 is connected to the nodes 540 and 542 of the respective second and third driver stages 502a, 504. The NMOS transistor 556 is connected between the output node 560 and the second voltage rail. The transistor 554 has its gate connected to the junction of the I1 current source 576 and a common gate cascode NMOS transistor 578 at a node 544. The transistor 578 has its gate connected to a bias signal bnc. The NMOS transistor 556 has its gate connected to the junction of the I2 current source 528 and the MP2 PMOS transistor 526 at a node 546.

If current loading at the output node 560 causes the VBL output voltage to drop, the voltage at the node 542 also drops and the current flow through the MP3 PMOS transistor 580 will drop. Accordingly, the current through the cascode transistor 578 will increase. When the current flow through the cascode transistor 578 is greater than the I1 current level, the bias voltage at the node 544 will decrease, turning on the PMOS transistor 554 to deliver additional current to the output node 560 to increase the VBL voltage level. Since the transistor 554 is directly connected to the first voltage rail it can deliver the full Vdd voltage.

If the VBL voltage at the output node 560 increases, the voltage at the nodes 540 and 542 increases and current through the transistors 526 and 580 accordingly also increases. If the current through the transistor 526 is greater than the I2 current level, the bias voltage at the node 546 will increase, turning on the NMOS transistor 556 to sink current from the output node 560 and reduce the VGL voltage level.

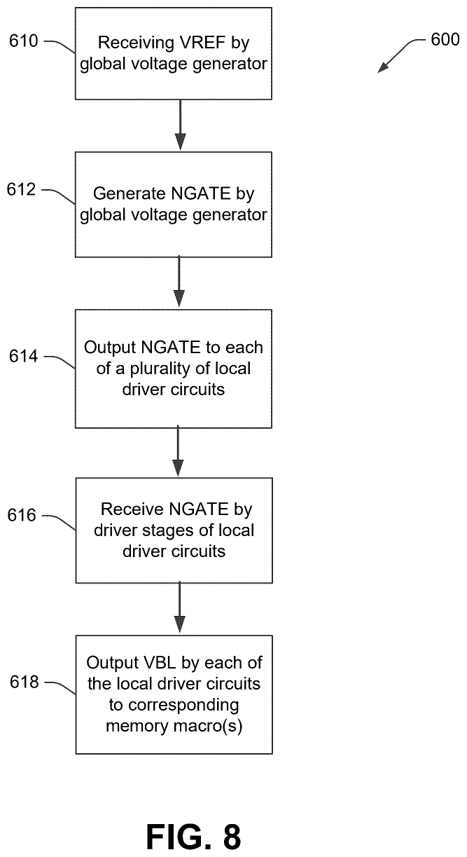

FIG. 8 illustrates a voltage regulator method 600 in accordance with some embodiments. With reference to FIG. 2 discussed above, the method 600 includes receiving a reference voltage VREF by a global voltage generator circuit 100 at operation 610. At operation 612, a gate control signal NGATE is generated by the global voltage generator circuit 100. In some examples, generating the gate control signal NGATE includes comparing the gate control signal to the reference voltage by a differential amplifier 110 such that the gate control signal NGATE replicates the reference voltage VREF. In other words, the voltage level of NGATE is the same as or very close to the VREF voltage level. The gate control signal NGATE is output by the global voltage generator circuit 100 to each of a plurality of local driver circuits 200 at operation 614. The gate control signal NGATE is received by a plurality of driver stages 201, 202 of the each of a plurality of local driver circuits 200 at operation 616. At operation 618, a memory control signal VBL is output by each of the plurality of local driver circuits 200 to a corresponding memory macro 20 (FIG. 1) or a group of corresponding memory macros 20. The memory control signal VBL is output by a buffer stage 203 of each of the local driver circuits 200. Further, the memory control signal VBL replicates the reference voltage signal VREF.

Aspects of the disclosure thus provide a voltage regulator system that includes distributed local driver circuits that are compact with a push-pull drive stage. The local driver circuits operate with low standby power, and can drive large memory arrays without suffering IR issues. The distributed local driver circuits each receive a bias voltage from a global voltage regulator that generates an accurate output signal using a feedback loop to replicates a received reference voltage.

In accordance with some embodiments, a voltage regulator circuit includes a global voltage generator circuit with a differential amplifier having a first input terminal configured to receive a reference voltage signal, a second input terminal and an output terminal. A feedback loop is connected between the output terminal of the error amplifier and the second input terminal of the differential amplifier. A plurality of driver circuits each include a first driver stage with an input terminal connected to the output terminal of the differential amplifier, a second driver stage with an input terminal connected to the output terminal of the differential amplifier and an output node, and a buffer stage connected to the output node of the second amplifier stage and having an output terminal.

In accordance with further example embodiments, a memory system, includes a plurality of memory macros that each have an array of memory cells. A global voltage generator circuit has a reference input terminal configured to receive a reference voltage and an output terminal configured to output a gate signal that replicates the reference voltage. A plurality of driver circuits each have an input terminal connected to the output terminal of the global generator circuit, and an output terminal connected to a corresponding one of the plurality of memory macros. The driver circuits are each configured to output a control signal that replicates the reference voltage, wherein the plurality of driver circuits do not include a compensation capacitor.

In accordance with still further example embodiments, a voltage regulator method includes receiving a reference voltage by a global voltage generator circuit, and generating a gate control signal by the global voltage generator circuit. Generating the gate control signal includes comparing the gate control signal to the reference voltage by a differential amplifier such that the gate control signal replicates the reference voltage. The gate control signal is output by the global voltage generator circuit to each of a plurality of local driver circuits. The gate control signal is received by a plurality of driver stages of the each of a plurality of local driver circuits. A memory control signal is output that replicates the reference voltage signal by a buffer stage of each of the plurality of local driver circuits.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A voltage regulator circuit, comprising:
a global voltage generator circuit comprising:
a differential amplifier having a first input terminal configured to receive a reference voltage signal, a second input terminal and an output terminal;
a feedback loop connected between the output terminal of the error amplifier and the second input terminal of the differential amplifier;
a plurality of driver circuits, each of the driver circuits comprising:
a first driver stage including an input terminal connected to the output terminal of the differential amplifier;
a second driver stage including an input terminal connected to the output terminal of the differential amplifier and an output node;
a buffer stage connected to the output node of the second amplifier stage and having an output terminal.

2. The voltage regulator circuit of claim 1, wherein the feedback loop includes an amplifier circuit connected to the output terminal of the differential amplifier.

3. The voltage regulator circuit of claim 2, wherein the amplifier circuit of the feedback loop includes a source follower amplifier.

4. The voltage regulator circuit of claim 1, further comprising a compensation capacitor connected to the output terminal of the differential amplifier.

5. The voltage regulator circuit of claim 1, wherein the first driver stage includes a first source follower stage connected to the output terminal of the differential amplifier, and wherein the second driver stage includes a second source follower stage connected to the output terminal of the differential amplifier.

6. The voltage regulator circuit of claim 5, wherein the buffer stage includes a push-pull amplifier connected to an output node of the second driver stage.

7. The voltage regulator circuit of claim 6, wherein the push-pull amplifier includes a current-mirror push-pull circuit.

8. The voltage regulator circuit of claim 6, wherein the push-pull amplifier includes a transconductance amplifier circuit.

9. The voltage regulator circuit of claim 1, wherein the buffer stage is configured to provide an output signal that replicates the reference voltage signal.

10. The voltage regulator circuit of claim 1, wherein the first driver stage includes a first NMOS transistor and the input terminal of the first driver stage includes a gate terminal of the first NMOS transistor, and wherein the second driver stage includes a second NMOS transistor and the input terminal of the second driver stage includes a gate terminal of the second NMOS transistor.

11. The voltage regulator circuit of claim 1, wherein the first driver stage includes a first PMOS transistor and the input terminal of the first driver stage includes a gate terminal of the first PMOS transistor, and wherein the second driver stage includes a second PMOS transistor and the input terminal of the second driver stage includes a gate terminal of the second PMOS transistor.

12. The voltage regulator circuit of claim 1, wherein the plurality of driver circuits do not include a feedback loop.

13. A memory system, comprising:
a plurality of memory macros, each including an array of memory cells;
a global voltage generator circuit having a reference input terminal configured to receive a reference voltage and an output terminal configured to output a gate signal that replicates the reference voltage; and
a plurality of driver circuits, each of the driver circuits having an input terminal connected to the output terminal of the global generator circuit, and an output terminal connected to a corresponding one of the plurality of memory macros configured to output a control signal that replicates the reference voltage, wherein the plurality of driver circuits do not include a compensation capacitor.

14. The memory system of claim 13, wherein the global voltage generator circuit comprises:
a differential amplifier having the input terminal and the output terminal of the global voltage generator circuit;
a feedback loop including a common source amplifier; and
a compensation capacitor connected between the common source amplifier and the output terminal.

15. The memory system of claim 13, wherein the common source amplifier comprises:
a first transistor having a gate terminal connected to the output terminal of the global voltage generator circuit, a first source/drain (S/D) terminal connected to a first voltage rail, and a second S/D terminal connected to a feedback node, wherein the feedback node is connected to the second input of the differential amplifier;
a second transistor having a first S/D terminal connected to the feedback node, a second S/D terminal, and a gate terminal connected to the second S/D terminal of the second transistor;
a current source connected between a second voltage rail and the second S/D terminal of the second transistor; and
wherein the compensation capacitor is connected between the second voltage rail and the output terminal.

16. The memory system of claim 13, wherein each of the driver circuits comprises:
a first driver stage including an input terminal connected to the output terminal of the differential amplifier;
a second driver stage including an input terminal connected to the output terminal of the differential amplifier and an output node;
a buffer stage connected to the output node of the second amplifier stage and having an output terminal.

17. A method, comprising:
receiving a reference voltage by a global voltage generator circuit;
generating a gate control signal by the global voltage generator circuit, including comparing the gate control signal to the reference voltage by a differential amplifier such that the gate control signal replicates the reference voltage;
outputting the gate control signal by the global voltage generator circuit to each of a plurality of local driver circuits;
receiving the gate control signal by a plurality of driver stages of each of a plurality of local driver circuits; and
outputting a memory control signal that replicates the reference voltage signal by a buffer stage of each of the plurality of local driver circuits.

18. The method of claim 17, wherein each of the plurality of local driver circuits outputs the memory control signal to a corresponding memory macro.

19. The method of claim 17, wherein receiving the gate control signal by the plurality of driver stages of the each of a plurality of local driver circuits includes amplifying the received the gate control signal by a source follower amplifier stage.

20. The method of claim 17, wherein outputting the memory control signal that replicates the reference voltage signal by the buffer stage of each of the plurality of local driver circuits includes processing the gate control signal by a push-pull buffer circuit.
